(19) United States
(12) Patent Application Publication
(10) Pub. No.: US 2007/0082460 A1
(43) Pub. Date: Apr. 12, 2007

(54) WAFER PROCESSING METHOD AND WAFER PROCESSING APPARATUS

(75) Inventor: Hiroyuki Ishida, Tokorozawa-shi (JP)

Correspondence Address: SUGHRUE MION, PLLC, 2100 PENNSYLVANIA AVENUE, N.W., SUITE 800, WASHINGTON, DC, 20037, US

(73) Assignee: BRIDGESTONE CORPORATION

(21) Appl. No.: 11/537,023

(22) Filed: Sep. 29, 2006

(30) Foreign Application Priority Data
Oct. 3, 2005 (JP) P2005-290422

(51) Int. Cl. H01L 21/30; H01L 21/46

(52) U.S. Cl. 438/455

(57) ABSTRACT

A method of processing a wafer includes a masking process for providing a mask on a surface of a film-formed wafer except for a wafer peripheral portion, and polishing process for spraying a processing liquid containing an inorganic material onto the wafer peripheral portion. According to the method of processing a wafer, it is possible to easily remove impurities existing on a wafer peripheral portion.

### RELATED APPLICATION

This application claims benefit of priority under 35 USC 119 based on Japanese Patent Application 2005-290422, filed Oct. 3, 2005, the entire contents of which are incorporated by reference herein.

### BACKGROUND OF THE INVENTION

1. Field of the Invention

The present invention relates to a method of processing and polishing a wafer, which can easily remove impurities existing on a wafer peripheral portion.

2. Description of the Related Art

The related art will be described with reference to FIGS. 2 to 4. FIG. 3 is a schematic sectional view illustrating a wafer in an intermediate process of manufacturing a device. On a silicon wafer 100, insulating films 101 and 102 made of silicon dioxide (SiO₂) and conductive films 103a, 103b, and 103c made of aluminum (Al) are deposited. As a combination of a film forming process, an etching process, a removing process, and the like is performed, the insulating films 101 and 102 and the conductive films 103a, 103b, and 103c are deposited on the surface of the silicon wafer 100. After a predetermined process, a chip 100b is cut out from the silicon wafer 100 so as to be used, as shown in FIG. 2.

In this case, it is difficult to adequately remove the insulating films and the like which have been removed in the removing process. Therefore, when impurities 104 remain on the silicon wafer 100, a film 102 is further laminated on the impurity 104, as shown in FIG. 3. As a result, as shown in FIG. 4, cracks 105 and 106 occurs in the insulating films 101 and 102, so that the insulating films 101 and 102 are easily separated. Then, the separated films 101 and 102 as impurities are likely to be adhered on the surface of the silicon wafer 100. Therefore, device characteristics are degraded. For example, junction leak current increases, and pressure resistance of a gate oxide film is degraded. Such degradation is regarded as one of causes which affect the reliability of the device.

This, phenomenon frequently occurs in a wafer peripheral portion 100a not used as a device, as shown in FIG. 2, that is, a non-used region (surplus region). This is considered because impurities are easily deposited due to the shape of the endportion of the wafer so as to be easily deposited, and as the impurity 104 remains on the insulating film formed on the wafer peripheral portion 100a, the separation of the films 101 and 102 occurs.

In order to solve the above-described problems, technologies have been suggested in which a laminated film formed on the wafer peripheral portion 100a of the silicon wafer is removed, and thus it possible to prevent the deposition of the impurity 104 to manufacture a device having a small amount of impurity 104. For example, a chemical mechanical planarization (CMP) method is exemplified (for example, see Japanese Patent No. 3111928 and Japanese Patent Application Laid-Open No. 2004-327466).

In the CMP method according to the related art, however, the price of equipment is huge, and a process is complicated. For example, in a process disclosed in Japanese Patent No. 3111928, an etchant of wet processing or a gas type of plasma processing needs to be changed depending on a film forming material. Further, Japanese Patent Application Laid-Open No. 2004-327466 discloses a technique in which only an end portion of wafer is polished by a rotating table provided with a polishing pad. However, as mechanical polishing is performed on a silicon wafer, chipping occurs in the end portion of the silicon wafer, surface roughness becomes large, the strength of the silicon wafer is reduced, or impurities enter into an air space formed on the surface of the silicon wafer. Then, the impurities which have not been removed in a cleaning process may cause the reliability of the device to be degraded.

Therefore, such a wafer processing method is required, that can easily remove impurities existing on a wafer peripheral portion.

### SUMMARY OF THE INVENTION

1. A method of processing a wafer includes

a masking process for providing a mask on a surface of a film-formed wafer except for a wafer peripheral portion; and

a polishing process for spraying a processing liquid containing an inorganic material onto the wafer peripheral portion.

2. The method of processing a wafer, wherein the inorganic material is silicon carbide powder having a particle diameter of about 0.1 μm to about 50 μm.

3. The method of processing a wafer, wherein the mask is a non-contact mask.

4. A wafer processing apparatus includes spray nozzles that sprays a processing liquid on to the wafer peripheral portion, and a mask that is disposed on a surface of the wafer except for a wafer peripheral portion.

5. The wafer processing apparatus, wherein the inorganic material is silicon carbide powder having a particle diameter of about 0.1 to about 50 μm.

6. The wafer processing apparatus, wherein the mask is a non-contact mask.

7. The wafer processing apparatus, wherein the space between the mask outer circumferential portion and the wafer is narrow.

8. The wafer processing apparatus, wherein the spray nozzles is movable.

### BRIEF DESCRIPTION OF THE DRAWINGS

FIG. 1 is a schematic side view illustrating a wafer processing apparatus according to an embodiment of the invention;

FIG. 2 is a diagram illustrating a wafer peripheral portion;

FIG. 3 is a schematic sectional view showing a state where impurities are deposited on a wafer surface; and

FIG. 4 is a partially enlarged sectional view showing a state where impurities are deposited on the wafer surface.

### DETAILED DESCRIPTION OF THE INVENTION

Hereinafter, the preferred embodiment of the invention will be described. However, the invention is not limited to the following embodiment. In the drawings, like reference numerals will be attached to elements having the same function and operation, and the description thereof will be omitted.

(Wafer Processing Apparatus)

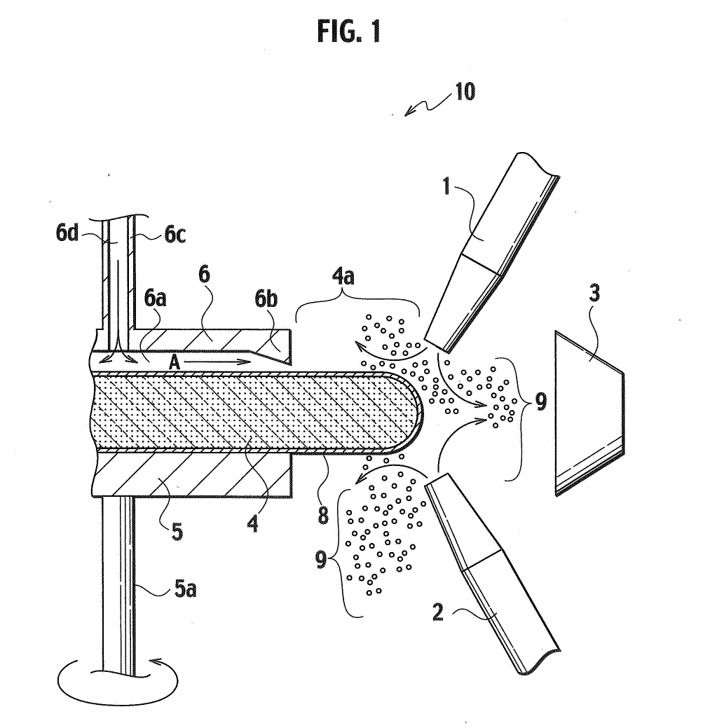

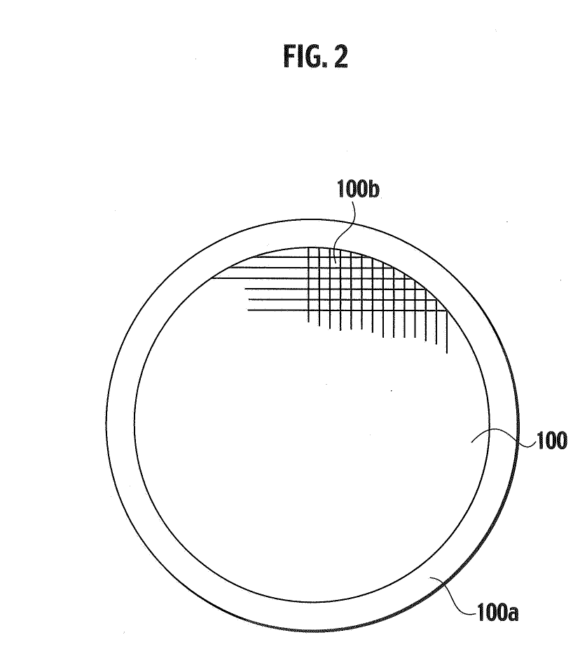

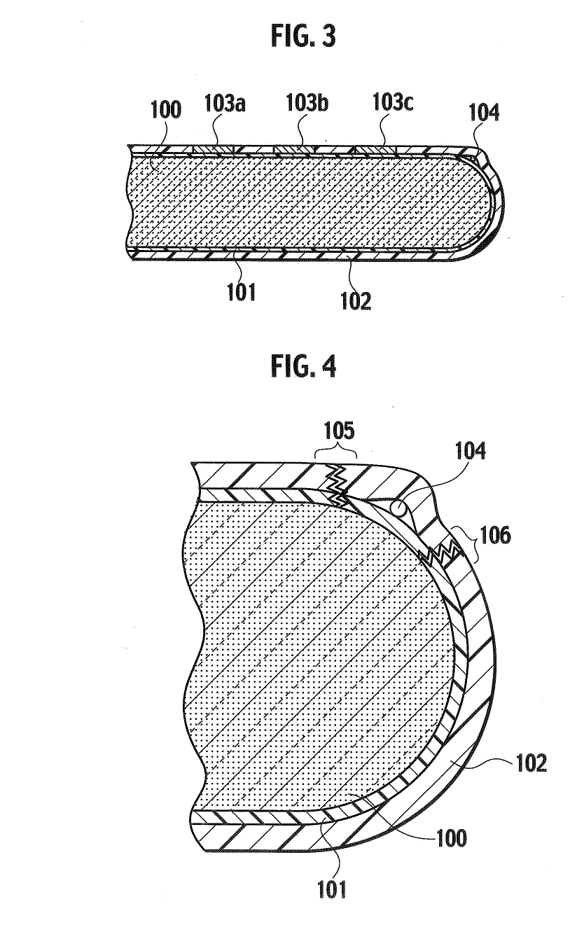

As shown in FIG. 1, a wafer processing apparatus 10 according to an embodiment of the invention includes a vacuum chuck 5 that fixes a wafer 4, a mask 6 that is disposed on a surface of the wafer 4 except for a wafer peripheral portion 4a, spray nozzles 1 and 2 that sprays a processing liquid onto the wafer peripheral portion 4a, and a suction machine 3 that sucks powder.

The structures of the spray nozzles 1 and 2 are not limited, if they can spray a processing liquid onto the wafer peripheral portion 4a. For example, as shown in FIG. 1, in a state where the spray nozzles 1 and 2 are fixed, the vacuum chuck 5 may be rotated while using a vacuum chuck shaft 5a as a shaft. Further, in a state where the wafer 4 is fixed, the spray nozzles 1 and 2 may be rotated. That is, the spray nozzles 1 and 2 may be movable.

Although the mask 6 is not limited to a specific mask, it is preferable to use a non-contact mask 6 such that the mask 6 does not contact with the surface of the wafer 4. For example, the mask 6 is disposed to face the vacuum chuck 5 so as not to contact with each other, with the wafer 4 interposed therebetween. Further, the mask 6 can be supported by a mask supporting portion 6. More preferably, an air current A is fed into a mask inner portion 6a from a mask hollow portion 6d of a mask indicating portion 6c and the pressure of the mask inner portion 6a is increased, such that the processing liquid is not supplied to the surface of the wafer 4. Further, in order to effectively prevent the processing liquid from being supplied to the surface of the wafer 4, it is preferable to narrow the space between a mask outer circumferential portion 6b corresponding to the outlet of the air current A, and the wafer 4.

(Wafer Processing Method)

A method of processing a wafer according to an embodiment of the invention includes a masking process and a polishing process. In the masking process, the mask 6 is provided on the surface of the film-formed wafer 4 except for the wafer peripheral portion 4a. In the polishing process, a processing liquid containing an inorganic material 9 is sprayed onto the wafer peripheral portion 4a. Hereinafter, the respective processes will be described in detail.

(a) Masking Process

The film-formed wafer 4 is fixed to the vacuum chuck 5. Examples of a film 8 include various films, such as a conductive film, an insulating film, and the like, which are formed in manufacturing a semiconductor wafer. Examples of a method of forming a film include a chemical vapor deposition (CVD) method, an evaporation method, a spin-coating method, and the like. Next, the mask 6 is provided on the surface of the wafer 4 except for the wafer peripheral portion 4a. Although the mask 6 is not limited to a specific mask, a non-contact mask is preferable as the mask 6. FIG. 1 shows the non-contact mask 6. Preferably, the pressure of the mask inner portion 6a is increased, such that the processing liquid is not supplied to the surface of the wafer.

(b) Polishing Process

Next, the processing liquid containing the inorganic material 9 and pure water is sprayed onto the wafer peripheral portion 4a. Further, the film 8 of the wafer peripheral portion 4a is polished. As for the inorganic material 9, silicon-carbide (SiC) powder having a particle diameter of about 0.1 to about 50 μm is preferably used. Here, in the claims and specification of the invention, a ‘particle diameter’ is analyzed as opening reference of a sieve. For example, particles with a particle diameter of about 1 mm or less refer to particles passing through a sieve of which the opening has a diameter of about 1 mm. As silicon-carbide powder having high purity is used, impurities do not remain, and surface roughness of the processed wafer 4 does not become excessively large. As specific examples of the inorganic material 9, hard materials are exemplified, including silicon-carbide powder, silicon dioxide (SiO₂), boron carbonate, diamond, and the like. Among them, any one may be used as the inorganic material 9, if it is available in the market and can be obtained. However, silicon-carbide powder is preferably used in terms of increasing purity without polluting the wafer 4. As for silicon-carbide powder, silicon-carbide powder which is explained in a silicon-carbide powder field of the present specification is preferably used. Preferably, the particle diameter of powder is in the range of about 0.1 to about 50 μm. More preferably, the particle diameter of powder is in the range of about 2 to about 10 μm. When the particle diameter is about 10 μm or less, the surface roughness of the processed wafer 4 can be set to about 0.1 μm or less. As for pure water, ultrapure water may be used, in addition to water which is typically referred to as pure water. A processing liquid (SiC powder+pure water) may be collected so as to be reused. Further, pulverized powder is sucked by the suction machine 3. In this way, processing is performed on the wafer 4.

Finally, when the wafer is provided with the plurality of films 8, it is preferable that the above-described (a) and (b) processes be performed after performing at least one film-forming process among a plurality of film-forming processes. During the film-forming process of the wafer 4, the (a) and (b) processes are performed at appropriate timing, thereby preventing impurities from being deposited. As a result, it is possible to prevent the film 8 from being removed. When the wafer is used in a device, the reliability of the device increases.

According to this embodiment, a processing apparatus, such as a plasma processing apparatus, having a complex structure, is not needed. Further, it is possible to simplify the process, because only a process where the processing liquid containing the inorganic material 9 is sprayed at high pressure is performed. Moreover, the surface roughness Ra after processing can be set within a range of 0.005 to 0.1 μm. Therefore, impurities generated during an etching process hardly remain in the wafer peripheral portion 4a. Further, as for the processing liquid used in the polishing process, pure water and the inorganic material 9 are mixed in advance, which makes it possible to supply a predetermined amount of processing liquid at all times. As a result, it is possible to reduce unevenness of the surface of the wafer 4.

(Silicon-Carbide Powder)

As for silicon-carbide powder, there is no limitation in a crystal polymorphism, a consumed amount, purity, a manufacturing method thereof, and the like, as long as it is silicon-carbide powder. For any purpose, proper silicon-carbide powder can be selected.

As for a polymorphism of silicon-carbide crystal, 4H, 6H, 15R, 3C, and the like are exemplified, among which 6H is preferably used. Preferably, one type of polymorph is misused independently. However, two types of polymorphisms may be used.

As for purity of the silicon-carbidepowder, it is preferable that purity be high in terms of preventing impurities from being adhered on the wafer 4. Specifically, it is preferable that the content of each impurity element be about 0.5 ppm or less.

Here, the content of an impurity element is an impurity content obtained by a chemical analysis and has a meaning as a reference value. Practically, evaluation also differs depending on whether the impurity elements are uniformly distributed in the silicon-carbide single crystal or locally distributed in portions thereof Here, the ‘impurity element’ refers to an element which belongs to group I to group XVII and is higher than atomic number of 3 (excluding carbon atom, oxygen atom, and silicon atom) in the periodic table of Nomenclature of Inorganic Chemistry (IUPAC recommendation 1989). Further, when a dopant element such as nitrogen or aluminum is intentionally added so as to impart n-type or p-type conductivity to growing silicon-carbide single crystal, it is also excluded.

Silicon-carbide is obtained through the following process. For example, at least one type of silicon compound as a silicon source, at least one type of organic compound as a carbon source which generates carbon through heating, and a polymerization or cross-linking catalyst are dissolved in a solvent and then dried so as to obtain powder. Further, the obtained powder is baked in a non-oxidation atmosphere.

As for a silicon compound, a liquid compound and a solid compound can be used together. However, at least one type is selected from a liquid compound. As for a liquid compound, alkoxysilane and alkoxysilane polymer are preferably used. As for alkoxysilane, methoxysilane, ethoxysilane, propoxysilane, butoxysilane, and the like are exemplified, among which ethoxysilane is preferable in terms of handling. As for alkoxysilane, any one of monoalkoxysilane, dialkoxysilane, trialkoxysilane, and tetraalkoxysilane may be used. Among them, tetraalkoxysilane is preferably used. As for alkoxysilane polymer, low-molecular-weight polymer (oligomer), of which the polymerization degree is about 2 to about 15, and silicate polymer are exemplified. For example, tetraethoxysilane oligomer is exemplified. As for a solid compound, silicon oxides are exemplified, including SiO, silica sol (colloidal minute silica-containing solution including an OH group or alkoxyl group therein), and silicon dioxide (silica gel, minute silica, and quartz powder). One type of silicon compound may be used independently, and two or more types of silicon compounds may be used together. Among silicon compounds, tetraethoxysilane oligomer and a mixture of tetraethoxysilane oligomer and minute silica are preferable, because homogeneity or a handling property is excellent.

As for a silicon compound, a silicon compound having high purity is preferable. For example, a silicon compound in which the content of each impurity is about 20 ppm or less in the initial stage is preferable, and a silicon compound in which the content of each impurity is about 5 ppm or less is more preferable. As for an organic compound which generates carbon through heating, a liquid organic compound may be used independently, or a liquid organic compound and a solid organic compound may be used together. As for an organic compound which generates carbon through heating, an organic compound, of which the actual carbon ratio is high and which is polymerized or cross-linked through a catalyst or heating, is preferable. For example, resin monomer or prepolymer such as phenol resin, furan resin, polyimide, polyurethane, polyvinyl alcohol or the like is preferable. In addition, liquid materials such as cellulose, sucrose, pitch, and tar are exemplified. Among them, high purity resin is preferable, and phenol resin is more preferable. Further, resol-type phenol resin is particularly preferable. As for an organic compound which generates carbon through heating, one type of organic compound may be used independently, or two or more types of organic compounds may be used together.

The purity of an organic compound which generates carbon through heating can be appropriately selected for any purpose. However, when high-purity silicon carbide powder is needed, an organic compound which does not contain each metal of about 5 ppm or more is preferably used.

A polymerization or cross-linking catalyst can be suitably selected in accordance with an organic compound which generates carbon through heating. However, when the organic compound which generates carbon through heating is phenol resin or furan resin, a toluenesulphonic acid, a toluenecarboxylic acid, an acetic acid, an oxalic acid, a maleic acid, a sulfuric acid, and the like are preferable, among which a maleic acid is particularly preferable.

A ratio (hereinafter, abbreviated to ‘C/Siratio’) ofcarbon included in an organic compound generating carbon through heating to silicon included in the silicon compound is defined by performing elementary analysis on a carbide intermediate obtained by carbonizing a mixture of carbon and silicon at temperature of about 1000° C. Stoichiometrically, the percentage of free carbon in silicon carbide powder obtained when a C/Si ratio is about 3.0 becomes 0%. Practically, however, free carbon is generated at a low C/Si ratio, because of the sublimation of a SiO gas generated at the same time. Preferably, a compounding ratio is determined in advance such that an amount of free carbon in the obtained silicon carbide powder becomes appropriate. Typically, when baking is performed around 1 atmospheric pressure at temperature of more than about 1600° C., a C/Si ratio is set to 2.0 to 2.5, which makes it possible to suppress free carbon. If a C/Si ratio exceeds 2.5, an amount of free carbon drastically increases. However, when baking is performed in a state where the pressure of atmosphere is set to low pressure or high pressure, a C/Si ratio varies for obtaining pure silicon carbide powder. In this case, the range of C/Si ratio does not need to be limited.

Moreover, silicon carbide powder is also obtained by hardening a mixture of a silicon compound and an organic compound which generates carbon through heating. As for a hardening method, there are exemplified a cross-liking method through heating, a hardening method using a hardening catalyst, a method using an electron beam or radiant ray, and the like.

A hardening catalyst can be appropriately selected in accordance with types of organic compounds generating carbon through heating. In the case of phenol resin or furan resin, acids such as a toluenesulphonic acid, a toluenecarboxylic acid, an acetic acid, an oxalic acid, a hydrochloric acid, a sulfuric acid, a maleic acid, and the like, and an amine acid such as hexamine are preferably selected. When these hardening catalysts are used, the hardening catalysts are dissolved or dispersed in a solvent. As for a catalyst, there are exemplified lower alcohol (for example, ethyl alcohol), ethyl ether, acetone, and the like.

The silicon carbide powder obtained by the above process is baked in a non-oxidizing atmosphere, such as nitrogen or argon, at temperature of about 800 to about 1000° C. for about 30 to about 120 minutes. The silicon carbide powder becomes carbide through the baking. As the carbide is baked in a non-oxidizing atmosphere such as argon at temperature of about 1350 to about 2000° C., silicon carbide powder is generated. Temperature and time of baking can be appropriately selected in accordance with particle diameters of silicon carbide powder to be obtained. When the temperature ranges from about 1600 to about 1900° C., silicon carbide powder is effectively generated. In order to remove impurities and obtain high-purity silicon carbide powder after baking, it is preferable that heating treatment be performed at temperature of about 2000 to about 2400° C. for about 3 to about 8 hours.

The sizes of the silicon carbide powder obtained by the above process are not uniform. Therefore, classification or the like is performed so as to obtain a desired particle size. As for an average particle size of silicon carbide powder, a size of 10 to 700 μm is preferable, and a size of 100 to 400 μm is more preferable.

Moreover, nitrogen or aluminum can be introduced in the silicon carbide powder. When the nitrogen or aluminum is introduced at the time of manufacturing the silicon carbide powder, it may be uniformly mixed with the silicon source, the carbon source, an organic material composed of a nitrogen source or an aluminum source, and the polymerization or cross-linking catalyst. At this time, when a carbon source such as phenol resin, an organic material composed of nitrogen source such as hexamethylene tetramine, and a polymerization or cross-linking catalyst such as a maleic acid are dissolved in a solvent such as ethanol, it is preferable that a silicon source such as tetraethoxysilane oligomer be sufficiently mixed therewith.

As for an organic material composed of a nitrogen source, a material generating nitrogen through heating is preferable. For example, a highly polymerized compound (specifically, polyimide resin, nylon resin and the like) and various organic amines (specifically, hexamethylene tetramine, ammonia, triethylamine, a compound thereof, and salts) are exemplified. Among them, hexamethylene tetramine is preferable. Further, phenol resin that is synthesized with hexamine set to a catalyst and containing about 2.0 mmol or more of nitrogen with respect to 1 g of resin can also be appropriately used as a norganic material composed of the nitrogen source, the nitrogen being derived in the synthesizing process. One type of organic material composed of a nitrogen source may be used independently, and two types of organic materials may be used together. Moreover, an organic material composed of the aluminum source is not particularly limited but can be suitably selected for any purpose.

As for an organic material composed of a nitrogen source, when the silicon source and the carbon source are added at the same time, an organic material containing about 1 mmol or more of nitrogen per 1 g of silicon source is preferable, and an organic material containing about 80 to about 100 μg of nitrogen with respect to 1 g of a silicon source is preferable.

More specifically, various types of silicon carbide powder are listed as follows. As for one type of silicon carbide powder, high-purity alkoxysilane is used as a silicon source, a high-purity organic compound generating carbon through heating is used as a carbon source, and a mixture obtained by uniformly mixing these sources is baked under a non-oxidizing atmosphere. Then, preferable silicon carbide powder is obtained. As for another type of silicon carbide powder, high-purity alkoxysilane and high-purity alkoxysilane polymer are set to a silicon source, a high-purity organic compound generating carbon through heating is used as a carbon source, and a mixture obtained by uniformly mixing these sources is baked under a non-oxidizing atmosphere. Then, preferable silicon carbide powder is obtained. As for a further type of silicon carbide powder, at least one selected from the group consisting of high-purity methoxysilane, high-purity ethoxysilane, high-purity propoxysilane, and high-purity butoxysilane is used as a silicon source, a high-purity organic compound generating carbon through heating is used as a carbon source, and a mixture obtained by uniformly mixing these sources is baked under a non-oxidizing atmosphere. Then, preferable silicon carbide powder is obtained. As for a still further type of silicon carbide powder, at least one selected from the group consisting of high-purity methoxysilane, high-purity ethoxysilane, high-purity propoxysilane, high-purity butoxysilane, and polymer thereof, of which the polymerization degree is about 2 to about 15, is used as a silicon source, a high-purity organic compound generating carbon through heating is used as a carbon source, and a mixture obtained by uniformly mixing these sources is baked under a non-oxidizing atmosphere. Then, preferable silicon carbide powder is obtained. As for a still further type of silicon carbide powder, at least one selected from the group consisting of high-purity monoalkoxysilane, high-purity dialkoxysilane, high-purity trialkoxysilane, high-purity tetraalkoxysilane, and polymer thereof, of which the polymerization degree is about 2 to about 15, is used as a silicon source, a high-purity organic compound generating carbon through heating is used as a carbon source, and a mixture obtained by uniformly mixing these sources is baked under a non-oxidizing atmosphere. Then, preferable silicon carbide powder is obtained.

### Modification of Embodiment

Although the invention has been described using the embodiment, the descriptions and drawings composing a portion of the disclosure do not limit the invention. Various substitute embodiments and operation techniques will be apparently understood by those skilled in the art through the disclosure. For example, in the above-described embodiment, processing is performed on the film-formed wafer. The ‘film-formed wafer’ is not limited to a wafer which has been subjected to a plurality of film forming processes in a device manufacturing process. Therefore, after one film forming process among the plurality of film forming processes is performed in the device manufacturing process, this embodiment maybe embodied. As such, the invention may include various embodiments which are not described therein. Therefore, the scope of the invention is determined only by the invention specified item relating to claims from the above descriptions.

What is claimed is:

1. A method of processing a wafer comprising:
a masking process for providing a mask on a surface of a film-formed wafer except for a wafer peripheral portion; and
a polishing process for spraying a processing liquid containing an inorganic material onto the wafer peripheral portion.

2. The method of processing a wafer according to claim 1, wherein the inorganic material is silicon carbide powder having a particle diameter of about 0.1 μm to about 50 μm.

3. The method of processing a wafer according to claim 1, wherein the mask is a non-contact mask.

4. A wafer processing apparatus comprising
spray nozzles that sprays a processing liquid onto the wafer peripheral portion, and
a mask that is disposed on a surface of the wafer except for a wafer peripheral portion.

5. The wafer processing apparatus according to claim 4,
wherein the inorganic material is silicon carbide powder having a particle diameter of about 0.1 to about 50 μm.

6. The wafer processing apparatus according to claim 4,
wherein the mask is a non-contact mask.

7. The wafer processing apparatus according to claim 4,
wherein the space between the mask outer circumferential portion and the wafer is narrow.

8. The wafer processing apparatus according to claim 4,
wherein the spray nozzles is movable.
